(19) United States
(12) Patent Application Publication
(10) Pub. No.: US 2011/0007766 A1
(43) Pub. Date: Jan. 13, 2011

(54) STRUCTURE FOR IMPROVING THE MIRROR FACET CLEAVING YIELD OF (Ga,Al,In,B)N LASER DIODES GROWN ON NONPOLAR OR SEMIPOLAR (Ga,Al,In,B)N SUBSTRATES

(75) Inventors: Robert M. Farrell, Goleta, CA (US); Matthew T. Hardy, Goleta, CA (US); Hiroaki Ohta, Goleta, CA (US); Steven P. DenBaars, Goleta, CA (US); James S. Speck, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/833,607

(22) Filed: Jul. 9, 2010

Related U.S. Application Data
(60) Provisional application No. 61/224,368, filed on Jul. 9, 2009.

(51) Int. Cl. H01S 5/343; H01S 5/34; H01L 33/04; H01L 33/30

(52) U.S. Cl. 372/45.01; 438/31; 977/755; 977/951; 257/E33.067; 438/47; 257/E33.005; 257/E33.023

(57) ABSTRACT

A structure for improving the mirror facet cleaving yield of (Ga,Al,In,B)N laser diodes grown on nonpolar or semipolar (Ga,Al,In,B)N substrates. The structure comprises a nonpolar or semipolar (Ga,Al,In,B)N laser diode including a waveguide core that provides sufficient optical confinement for the device's operation in the absence of p-type doped aluminum-containing waveguide cladding layers, and one of more n-type doped aluminum-containing layers that can be used to assist with facet cleaving along a particular crystallographic plane.

### CROSS-REFERENCE TO RELATED APPLICATIONS

This application claims the benefit under 35 U.S.C. Section 119(e) of co-pending and commonly assigned U.S. Provisional Patent Application Ser. No. 61/224,368, filed on Jul. 9, 2009, by Robert M. Farrell, Matthew T. Hardy, Hiroaki Ohta, Steven P. DenBaars, James S. Speck and Shuji Nakamura, entitled “STRUCTURE FOR IMPROVING THE MIRROR FACET CLEAVING YIELD OF (Ga,Al,In,B)N LASER DIODES GROWN ON NONPOLAR OR SEMIPOLAR (Ga,Al,In,B)N SUBSTRATES” attorney's docket number 30794.319-US-P1 (2009-762-1), which application is incorporated by reference herein.

This application is related to the following co-pending and commonly-assigned Patent Applications:

PCT international Patent Application Serial No. PCT/US2010/037629, filed on Jun. 7, 2010, by Arpan Chakraborty, You-Da Lin, Shuji Nakamura, and Steven P. DenBaars, entitled “ASYMMETRICALLY CLADDED LASER DIODE,” attorneys' docket number 30794.314-US-WO (2009-614-2), which application claims the benefit under 35 U.S.C. Section 119(e) of U.S. Provisional Application Ser. No. 61/184,668, filed Jun. 5, 2009, by Arpan Chakraborty, You-Da Lin, Shuji Nakamura, and Steven P. DenBaars, entitled “ASYMMETRICALLY CLADDED LASER DIODE,” attorneys' docket number 30794.314-US-P1 (2009-614-1); and

U.S. Utility application Ser. No. 12/795,360, filed on Jun. 7, 2010, by Arpan Chakraborty, You-Da Lin, Shuji Nakamura, and Steven P. DenBaars, entitled “LONG WAVELENGTH NONPOLAR AND SEMIPOLAR (Al,Ga,In)N BASED LASER DIODES,” attorneys' docket number 30794.315-US-U1 (2009-616-2), which application claims the benefit under 35 U.S.C. Section 119(e) of co-pending and commonly assigned U.S. Provisional Application Ser. No. 61/184,729, filed on Jun. 5, 2009, by Arpan Chakraborty, You-Da Lin, Shuji Nakamura, and Steven P. DenBaars, entitled “LONG WAVELENGTH m-PLANE (Al,Ga,In)N BASED LASER DIODES,” attorneys' docket number 30794.315-US-P1 (2009-616-1);

which applications are incorporated by reference herein.

### BACKGROUND OF THE INVENTION

1. Field of the Invention

This invention relates to a structure for improving the mirror facet cleaving yield of (Ga,Al,In,B)N laser diodes grown on nonpolar or semipolar (Ga,Al,In,B)N substrates.

2. Description of the Related Art

(Note: This application references a number of different publications as indicated throughout the specification by one or more reference numbers within brackets, e.g., [Ref(s). x]. A list of these different publications ordered according to these reference numbers can be found below in the section entitled “References.” Each of these publications is incorporated by reference herein.)

The usefulness of GaN and alloys of (Ga,Al,In,B)N has been well established for fabrication of visible and ultraviolet optoelectronic devices and high power electronic devices. Such devices include both laser diodes (LDs) and light emitting diodes (LEDs).

Current state-of-the-art (Ga,Al,In,B)N thin films, heterostructures, and devices are grown along the [0001] c-axis. The total polarization of such films consists of spontaneous and piezoelectric polarization contributions, both of which originate from the single polar [0001] c-axis of the würtzite (Ga,Al,In,B)N crystal structure. When (Ga,Al,In,B)N heterostructures are grown pseudomorphically, polarization discontinuities are formed at surfaces and interfaces within the crystal. These discontinuities lead to the accumulation or depletion of carriers at surfaces and interfaces, which in turn produce electric fields. Since the alignment of these polarization-induced electric fields coincides with the typical [0001] growth direction of (Ga,Al,In,B)N thin films and heterostructures, these fields have the effect of “tilting” the energy bands of (Ga,Al,In,B)N devices.

In c-plane (Ga,Al,In,B)N quantum wells, the “tilted” energy bands spatially separate the electron and hole wavefunctions. This spatial charge separation reduces the oscillator strength of radiative transitions and red-shifts the emission wavelength. These effects are manifestations of the quantum confined Stark effect (QCSE) and have been thoroughly analyzed for (Ga,Al,In,B)N quantum wells [Refs. 7, 8]. Additionally, the large polarization-induced electric fields can be partially screened by dopants and injected carriers [Ref 9], making the emission characteristics difficult to engineer accurately.

Furthermore, it has been theoretically predicted that pseudomorphic biaxial strain has little effect on reducing the effective valence band density of states in c-plane InₓGa₁₋ₓN quantum wells [Ref. 10]. This is in contrast to typical III-V zinc-blende InP- and GaAs-based quantum wells, where anisotropic strain-induced splitting of the top two valence bands leads to a significant reduction in the effective valence band density of states. A reduction in the effective valence band density of states leads to a substantial increase in the quasi-Fermi level separation for any given carrier density in typical III-V zinc-blende InP- and GaAs-based quantum wells. As a direct consequence of this increase in quasi-Fermi level separation, much smaller carrier densities are needed to generate optical gain [Ref 11]. However, in the case of the würtzite InₓGa₁₋ₓN crystal structure, the hexagonal symmetry and small spin-orbit coupling of the nitrogen atoms in biaxially strained c-plane InₓGa₁₋ₓN quantum wells produces negligible splitting of the top two valence bands [Ref. 10]. Thus, the effective valence band density of states remains much larger than the effective conduction band density of states in biaxially strained c-plane InₓGa₁₋ₓN quantum wells, and very high current densities are needed to generate optical gain in c-plane (Ga,Al,In,B)N LDs.

One approach to decreasing polarization effects in (Ga,Al,In,B)N devices is to grow the devices on nonpolar planes of the crystal [Ref 12]. These include the {11 2̅0} planes, known collectively as a-planes, and the {10 1̅0} planes, known collectively as m-planes. Such planes contain equal numbers of gallium and nitrogen atoms per plane and are charge-neutral. Subsequent nonpolar layers are equivalent to one another so the bulk crystal will not be polarized along the growth direction.

Another approach to reducing polarization effects in (Ga,Al,In,B)N devices is to grow the devices on semipolar planes of the crystal. The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another so the bulk crystal will have reduced polarization along the growth direction.

Unlike strained c-plane InₓGa₁₋ₓN quantum wells, it has been predicted that strained nonpolar or semipolar InₓGa₁₋ₓN quantum wells should exhibit anisotropic splitting of the top two valence bands, which should lead to a reduction in the effective valence band density of states for such structures [Ref 13]. Self-consistent calculations of many-body optical gain for compressively strained InₓGa₁₋ₓN quantum wells suggest that the peak gain is very sensitive to the effective valence band density of states and net quantum well polarization and that peak gain should increase dramatically as the angle between a general growth orientation and the c-axis increases, reaching a maximum for growth orientations perpendicular to the c-axis (i.e. on nonpolar planes) [Ref. 13].

Finally, commercial c-plane (Ga,Al,In,B)N LEDs and LDs do not exhibit any degree of optical polarization in their electroluminescence. Nonpolar or semipolar (Ga,Al,In,B)N LEDs and LDs, on the other hand, have demonstrated strong optical polarization in their electroluminescence [Refs. 14, 15]. This optical polarization can be attributed to anisotropic strain-induced splitting of the top two valence bands in compressively strained nonpolar or semipolar InₓGa₁₋ₓN quantum wells, leading to significant differences in the magnitude of various optical matrix elements. This optical polarization can potentially be exploited for a number of device applications.

Current conventional commercially-available (Ga,Al,In,B)N LD structures grown on the c-plane of the würtzite (Ga,Al,In,B)N crystal structure typically employ thin (≦4 nm) InGaN quantum wells (QWs) due to the presence of polarization-related electric fields. Thus, thick Al-containing waveguide cladding layers, such as AlGaN/GaN superlattices or bulk AlGaN, are needed to provide sufficient optical mode confinement in c-plane (Ga,Al,In,B)N LDs.

Unlike conventional (Ga,Al,In,B)N LDs grown on c-plane GaN substrates, the absence of polarization-related electric fields in m-plane light-emitting devices allows for the implementation of relatively thick (8 nm) InGaN QWs in m-plane (Ga,Al,In,B)N LEDs and LDs without a reduction in radiative efficiency [Ref 1]. These thick InGaN QWs can provide adequate transverse waveguiding of the optical mode without the need for Al-containing waveguide cladding layers [Refs. 2, 3]. Similar designs, involving the use of an InGaN-based separate confinement heterostructure with GaN cladding layers, can also alleviate the need for Al-containing waveguide cladding layers [Ref 4].

Previous studies have determined that the threshold current densities for m-plane (Ga,Al,In,B)N LDs with stripes orientated along the c-axis are lower than for LDs with stripes oriented along the a-axis [Ref 5]. Unlike c-plane (Ga,Al,In,B)N LDs, which are typically use the nonpolar {10 1̅0} m-planes for facet cleaving, orientation of lasers bars along the c-axis for m-plane (Ga,Al,In,B)N LDs necessitates facet cleaving along the polar {0001} c-planes of the crystal. Cleaving along the polar {0001} c-planes complicates the process, as the polarization between individual N-faces and Ga-faces increases the bond energy per unit area between the crystallographic planes. This makes it more difficult in general to obtain high-quality cleaves on polar planes than on nonpolar planes of the (Ga,Al,In,B)N würtzite crystal structure, reducing the facet uniformity and device yield for m-plane (Ga,Al,In,B)N LDs with stripes orientated along the c-axis.

Anisotropic tensile strain in relatively thick m-plane AlGaN layers has been shown to cause cracking along the polar {0001} c-planes of device structures grown on m-plane substrates [Ref. 6]. Although such uncontrolled cracking is not desirable for device manufacturing, thick Al-containing layers can be exploited to assist facet cleaving along the polar {0001} c-planes of the crystal. For the case of m-plane (Ga,Al,In,B)N LDs with thick InGaN QWs, thick n-type Al-containing layers can be used to assist facet cleaving along the polar {0001} c-planes without the need for p-type Al-containing waveguide cladding layers.

The use of p-type Al-containing waveguide cladding layers in conventional (Ga,Al,In,B)N LDs can introduce several manufacturing-related problems. In general, p-type Al-containing layers are usually higher resistivity than comparable p-type GaN layers, resulting in higher operation voltages for devices with p-type Al-containing layers than similar devices without p-type Al-containing layers. In addition, p-type Al-containing layers are typically grown at higher growth temperatures than comparable p-type GaN layers, which can thermally degrade high-indium-content InGaN QWs. The realization of nonpolar or semipolar (Ga,Al,In,B)N LDs without p-type Al-containing waveguide cladding layers should alleviate many of these problems.

Likewise, improved facet cleaving yields should lead to a number of advantages for nonpolar and semipolar (Ga,Al,In,B)N device manufacturers, including, but not limited to, better overall device yield, higher facet stability, higher catastrophic optical damage (COD) levels, and longer device lifetimes.

### SUMMARY OF THE INVENTION

To overcome the limitations in the prior art described above, and to overcome other limitations that will become apparent upon reading and understanding the present specification, the present invention discloses a structure for improving the mirror facet cleaving yield of (Ga,Al,In,B)N LDs grown on nonpolar or semipolar (Ga,Al,In,B)N substrates. The structure comprises a nonpolar or semipolar (Ga,Al,In,B)N LD including a waveguide core that provides sufficient optical confinement for the device's operation in the absence of p-type doped aluminum-containing waveguide cladding layers, and one of more n-type doped aluminum-containing layers that can be used to assist with facet cleaving along a particular crystallographic plane.

The p-type doped aluminum-containing waveguide cladding layer may be defined as an aluminum-containing layer that is used to provide sufficient optical confinement of light emitted from InGaN quantum wells in a conventional LD, the InGaN quantum wells in the conventional LD having a thickness of 4 nm or below.

The nonpolar or semipolar (Ga,Al,In,B)N LD may include a quantum well active region that functions as the waveguide core. The nonpolar or semipolar (Ga,Al,In,B)N LD may include a quantum well active region and one or more waveguiding layers, with a refractive index greater than that of GaN, optically coupled to the quantum well active region, the waveguiding layers and the quantum well active region functioning together as the waveguide core.

The quantum well active region, or the quantum well active region and the waveguiding layers, may provides enough material with a high index of refraction to effectively confine an optical mode of the device in the absence of the p-type doped aluminum-containing waveguide cladding layers.

A closest one of the n-type doped aluminum-containing layers may be less than, or greater than, 500 nm away from the active region.

The device may be free of n-type AlGaN cladding layers or comprise n-type AlInGaN cladding layers positioned to act as a cladding for the waveguide core, for example. The device may comprise a structure where there are no p-type Al-containing cladding layers.

The device may further comprise a laser cavity bounded by a first facet and a second facet, at opposite ends of the laser cavity, that function as the laser cavity's mirrors, wherein the first facet and the second facet are “as cleaved” facets that are more planar and straighter as compared to “as cleaved” facets in the device structure without the n-type doped aluminum-containing layers.

### BRIEF DESCRIPTION OF THE DRAWINGS

Referring now to the drawings in which like reference numbers represent corresponding parts throughout:

FIG. 1(a) is a cross-sectional schematic of the epitaxial structure of sample A, FIG. 1(b) is a cross-sectional schematic of the epitaxial structure of sample B, and FIG. 1(c) illustrates two periods of the 5 period MQW structure used in samples A and B.

FIG. 2(a) shows the calculated one-dimensional (1-D) transverse mode profile of sample A, plotting index of refraction and electric field intensity (arbitrary units, a.u.) as a function of position in sample A along the growth direction (micrometers, μm), and FIG. 2(b) shows the calculated 1-D transverse mode profile of sample B, plotting index of refraction and electric field intensity (a.u.) as a function of position in sample B along the growth direction (μm).

FIG. 3(a) is an optical micrograph of the top surface of sample A after scribing but before cleaving, and FIG. 3(b) is an optical micrograph of the top surface of sample B after scribing but before cleaving, wherein the vertical and horizontal scale is 20 μm in both FIG. 3(a) and FIG. 3(b), and the [10-10], [0001], and [11-20] directions are also shown.

FIG. 4(a) is an optical micrograph of the top surface of sample A after cleaving, and FIG. 4(b) is an optical micrograph of the top surface of sample B after cleaving, wherein the vertical and horizontal scale is 125 μm in both FIG. 4(a) and FIG. 4(b), and the [10-10], [0001], and [11-20] directions are also shown.

FIG. 5(a) is a histogram of facet cleaving yield per laser bar for sample A, and FIG. 5(b) is a histogram of facet cleaving yield per laser bar for sample B.

FIG. 6 is a flowchart illustrating a method of fabricating a semiconductor optoelectronic device.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Nomenclature

GaN and its ternary and quaternary compounds incorporating aluminum and indium (AlGaN, InGaN, AlInGaN) are commonly referred to using the terms (Al,Ga,In)N, III-nitride, Group III-nitride, nitride, Al_{(1-x-y)}In_{y}GaₓN where 0≦x≦1 and 0≦y≦1, or AlInGaN, as used herein. All these terms are intended to be equivalent and broadly construed to include respective nitrides of the single species, Al, Ga, and In, as well as binary, ternary and quaternary compositions of such Group III metal species. Accordingly, these terms comprehend the compounds AN, GaN, and InN, as well as the ternary compounds AlGaN, GaInN, and AlInN, and the quaternary compound AlGaInN, as species included in such nomenclature. When two or more of the (Ga, Al, In) component species are present, all possible compositions, including stoichiometric proportions as well as “off-stoichiometric” proportions (with respect to the relative mole fractions present of each of the (Ga, Al, In) component species that are present in the composition), can be employed within the broad scope of the invention. Accordingly, it will be appreciated that the discussion of the invention hereinafter in primary reference to GaN materials is applicable to the formation of various other (Al, Ga, In)N material species. Further, (Al,Ga,In)N materials within the scope of the invention may further include minor quantities of dopants and/or other impurity or inclusional materials.

Moreover, throughout this disclosure, the prefixes n-, p-, and p⁺⁺-before the layer material denote that the layer material is n-type, p-type, or heavily p-type doped, respectively. For example, n-GaN indicates the GaN is n-type doped.

One approach to eliminating the spontaneous and piezoelectric polarization effects in GaN or III-nitride based optoelectronic devices is to grow the III-nitride devices on nonpolar planes of the crystal. Such planes contain equal numbers of Ga (or group III atoms) and N atoms and are charge-neutral. Furthermore, subsequent nonpolar layers are equivalent to one another so the bulk crystal will not be polarized along the growth direction. Two such families of symmetry-equivalent nonpolar planes in GaN are the {11-20} family, known collectively as a-planes, and the {1-100} family, known collectively as m-planes. Thus, nonpolar III-nitride is grown along a direction perpendicular to the (0001) c-axis of the III-nitride crystal.

Another approach to reducing polarization effects in (Ga,Al,In,B)N devices is to grow the devices on semipolar planes of the crystal. The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index.

Technical Description

This invention describes a structure that can be used to improve the facet cleaving yield of (Ga,Al,In,B)N LDs grown on nonpolar or semipolar (Ga,Al,In,B)N substrates. The inventors have experimentally demonstrated these effects for (Ga,Al,In,B)N devices grown by metal organic chemical vapor deposition (MOCVD) on free-standing m-plane GaN substrates manufactured by Mitsubishi Chemical Co., Ltd. These substrates were grown by hydride vapor phase epitaxy (HVPE) in the c-direction and then sliced to expose the m-plane surface. The m-plane surface was prepared by chemical and mechanical surface treatment techniques. The substrates have threading dislocation densities of less than 5×10⁶ cm⁻², carrier concentrations of approximately 1×10¹⁷ cm³, and a root mean square (RMS) surface roughness of less than 1 nm, as measured by the manufacturer.

The MOCVD growth conditions were very similar to those typically used for c-plane (Ga,Al,In,B)N thin films. All MOCVD growth was performed at atmospheric pressure (AP), at typical VIII ratios (>3000), and at typical growth temperatures (>1000° C.). Trimethylgallium (TMGa) or triethylgallium (TEGa), trimethylindium (TMIn), trimethylaluminum (TMAl), ammonia (NH₃), Bis(cyclopentadienyl)magnesium (Cp₂Mg), and silane (SiH₄) were used as the Ga, In, Al, N, Mg, and Si precursors, respectively.

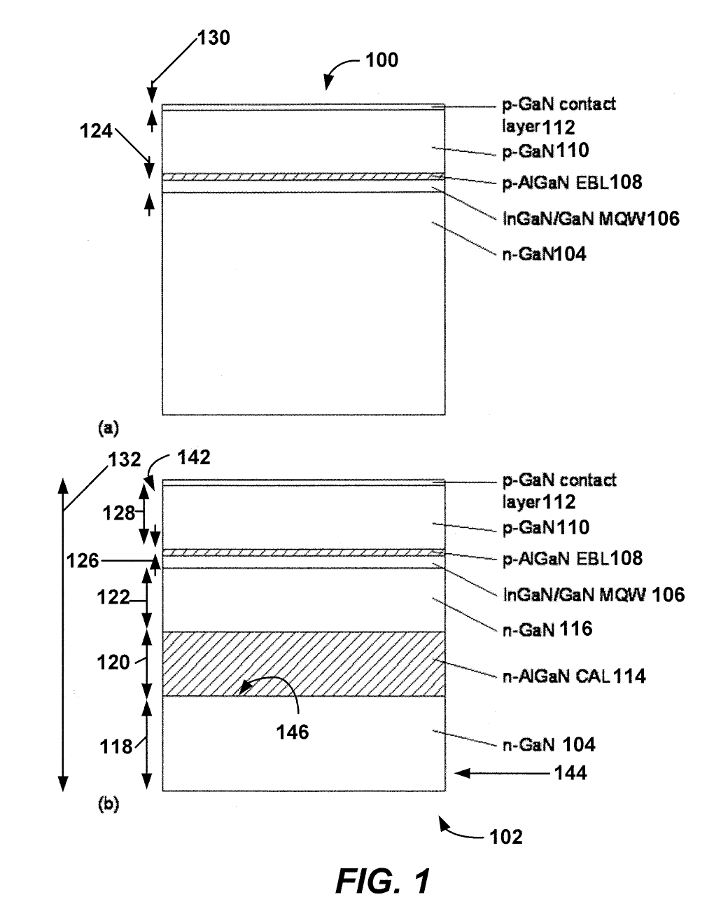

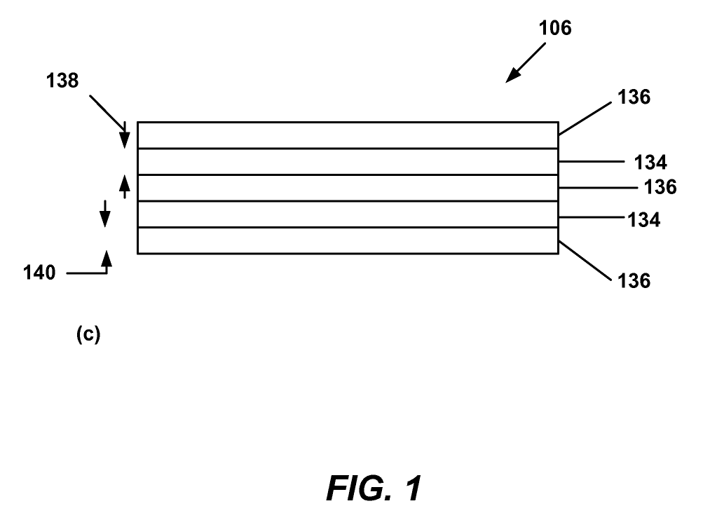

Two different samples (samples A 100 and B 102) were grown to evaluate the effect of thick n-type Al-containing layers on facet cleaving yield. Schematics of sample A 100 and B 102 are shown in FIG. 1 (a) and FIG. 1(b), respectively.

The first sample (sample A 100), which did not contain any thick Al-containing layers, was similar to AlGaN-cladding-free (ACF) LD structures reported elsewhere [Refs. 2, 3]. This ACF LD structure was comprised of a 10 μm thick Si-doped n-GaN template layer 104, a 5 period undoped In_{0.10}Ga_{0.90}N/GaN multiple-quantum-well (MQW) structure 106 with 8 nm thick In_{0.10}Ga_{0.90}N QWs and 8 nm thick GaN barriers, a 15 nm thick Mg-doped p-Al_{0.12}Ga_{0.88}N electron blocking layer 108, a 1 μm thick Mg-doped p-GaN cladding layer 110, and a 20 nm thick highly Mg-doped p⁺⁺-GaN contact layer 112. The only Al-containing layer in the entire structure was the 15 nm thick Mg-doped Al_{0.12}Ga_{0.88}N electron blocking layer 108.

The second sample (sample B 102), which was very similar to the first sample 100, contained an additional thick Al-containing cleave assistance layer 114 (CAL) to improve the facet cleaving yield. Sample B was comprised of a 10 μm thick Si-doped n-GaN template layer 104, a 1 μm thick Si-doped n-Al_{0.06}Ga_{0.94}N CAL 114, a 1 μm thick Si-doped n-GaN spacer layer 116, a 5 period undoped In_{0.10}Ga_{0.90}N/GaN MQW structure 106 with 8 nm thick In_{0.10}Ga_{0.90}N QWs and 8 nm thick GaN barriers, a 15 nm thick Mg-doped p-Al_{0.12}Ga_{0.88}N electron blocking layer 108, a 1 μm thick Mg-doped p-GaN cladding layer 110, and a 20 nm thick highly Mg-doped p⁺⁺-GaN contact layer 112. The only thick Al-containing layer in the entire structure was the 1 μm Si-doped n-Al_{0.06}Ga_{0.94}N CAL 114. The only p-type Al-containing layer in the entire structure was the 15 nm Mg-doped Al_{0.12}Ga_{0.88}N electron blocking layer 108.

Unlike conventional (Ga,Al,In,B)N LDs grown on c-plane GaN substrates, the structures described above contained relatively thick (8 nm) In_{0.10}Ga_{0.90}N QWs.

FIG. 1(a) and FIG. 1(b) also illustrate the thicknesses 118, 120, 122, 124, 126, and 128, 130 of layers 104, 114, 116, 106, 108, 110, and 112, respectively. The total thickness 132 of the device structure 102 is also shown.

FIG. 1(c) illustrates two periods of the 5 period MQW structure 106, comprising InGaN quantum wells 134 between GaN barriers 136, wherein the quantum wells 134 have a thickness 138 and the barriers 136 have a thickness 140.

Also shown in FIG. 1(a) and FIG. 1(b) are a first facet 142 and a second facet 144 of the LD. The device layers 106-112 are deposited on a surface 146 of the template layer 104, wherein the surface 146 is an m-plane of III-nitride, and the facets 142 and 144 are c-planes (perpendicular to the c-axis of III-nitride).

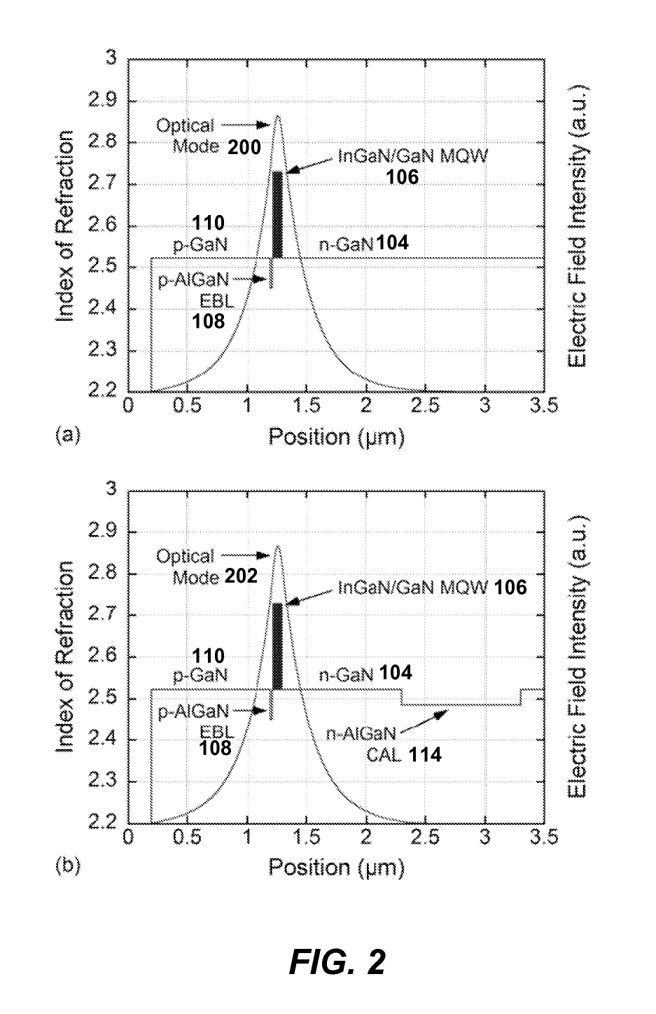

The calculated 1-D transverse mode profile 200 for sample A is presented in FIG. 2(a). The model used index of refraction values at a wavelength of 405 nm of 2.522, 2.487, 2.730, and 2.451 for GaN, Al_{0.06}Ga_{0.94}N, In_{0.10}Ga_{0.90}N, and Al_{0.12}Ga_{0.88}N layers, respectively [Ref 16]. As illustrated by the calculated mode profile 200, the thick In_{0.10}Ga_{0.90}N quantum wells (QWs) provided adequate transverse waveguiding of the optical mode 200 without the need for Al-containing waveguide cladding layers. The calculated transverse confinement factor, Γ, for this structure was 0.142. Also indicated in FIG. 2(a) are the n-GaN layer 104, p-AlGaN electron blocking layer (EBL) 108, and p-GaN layer 110.

FIG. 2(b) displays the calculated 1-D transverse mode profile 202 for sample B, which is very similar to sample A, except that it contains a 1 μm Si-doped n-Al_{0.06}Ga_{0.94}N CAL that is located 1 μm below the In_{0.10}Ga_{0.90}N/GaN MQW. As illustrated by the calculated mode profile 202, the 1 μm Si-doped n-Al_{0.06}Ga_{0.94}N CAL had little effect on the optical mode 202, which was guided primarily by the In_{0.10}Ga_{0.90}N/GaN MQW. The calculated transverse confinement factor, Γ, for this structure was 0.142, the same as structure A. Hence, even though sample B contains a thick n-type Al-containing CAL, it is still referred to as an ACF LD structure. Also indicated in FIG. 2(b) are the n-GaN layer 104, p-AlGaN EBL 108, p-GaN layer 110, and n-type AlGaN CAL 114.

Following the MOCVD growth, samples A and B were thinned by mechanical grinding and lapping to a thickness of about 50 μm. Next, a diamond-stylus-based wafer scribing tool was used in conjunction with a periodic skip-scribe technique to prepare the samples for facet cleaving. The skip-scribe technique consisted of scribing the epitaxial side of the wafer with a collinear set of periodic 85 μm skip steps and 115 μm scribe steps across the wafer. For both samples A and B, the scribe direction was aligned with the a-axis of the crystal. During the skip steps, the diamond stylus used to scribe the wafer was lifted up from the surface of the wafer, leaving the wafer unscribed for a distance of 85 μm. This 85 μm skip length is typically where a ridge waveguide LD structure would be located in the case of a fully processed LD sample. Similar stylus angles, stylus pressures, cut speeds, cut depths, and wafer mounting were used for scribing samples A and B.

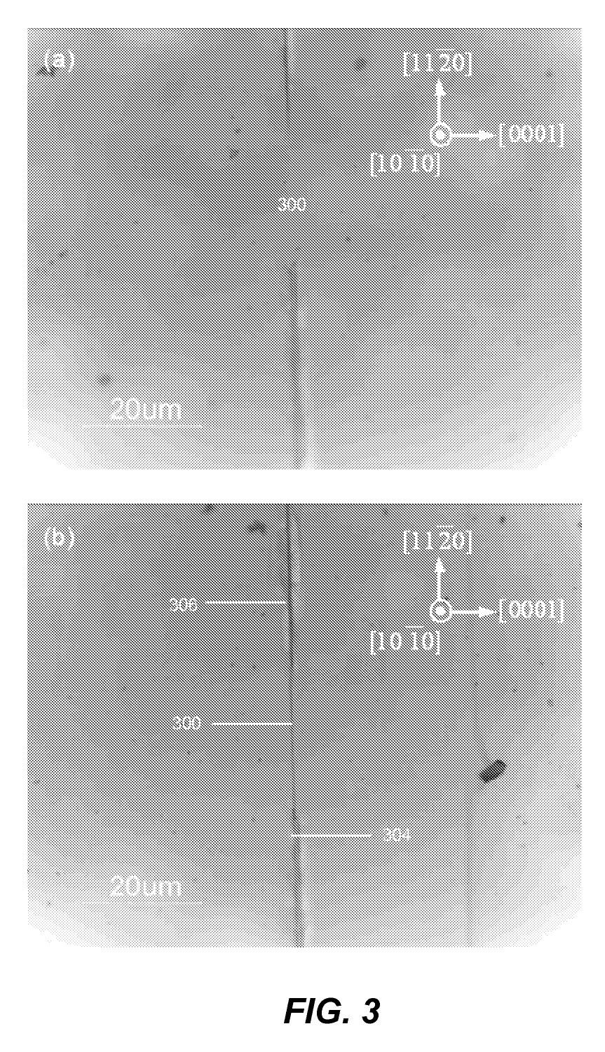

Representative optical micrographs of the top surfaces (in these cases the top surface of the p⁺⁺ contact layer 112) of samples A and B after scribing, but before cleaving, are presented in FIGS. 3(a) and 3(b), respectively. Both figures were taken at relatively high magnification (50×) and only show a single skip-scribe step. For sample A, the skipped region 300 did not crack during the scribing process. However, for sample B, the skipped region cracked spontaneously in a straight line 302 along the {0001} crystallographic plane during the scribing process, connecting the two adjacent scribe lines 304, 306. Although the exact mechanism is unknown, the inventors speculate that the spontaneous cracking 302 in sample B was related to accumulated strain energy in the anisotropically-strained thick n-type Al-containing CAL. In FIG. 3(a) and FIG. 3(b), the arrows indicate the [0001] and [11-20] crystal directions and the circle surrounding the dot indicates the [10-10] crystal direction.

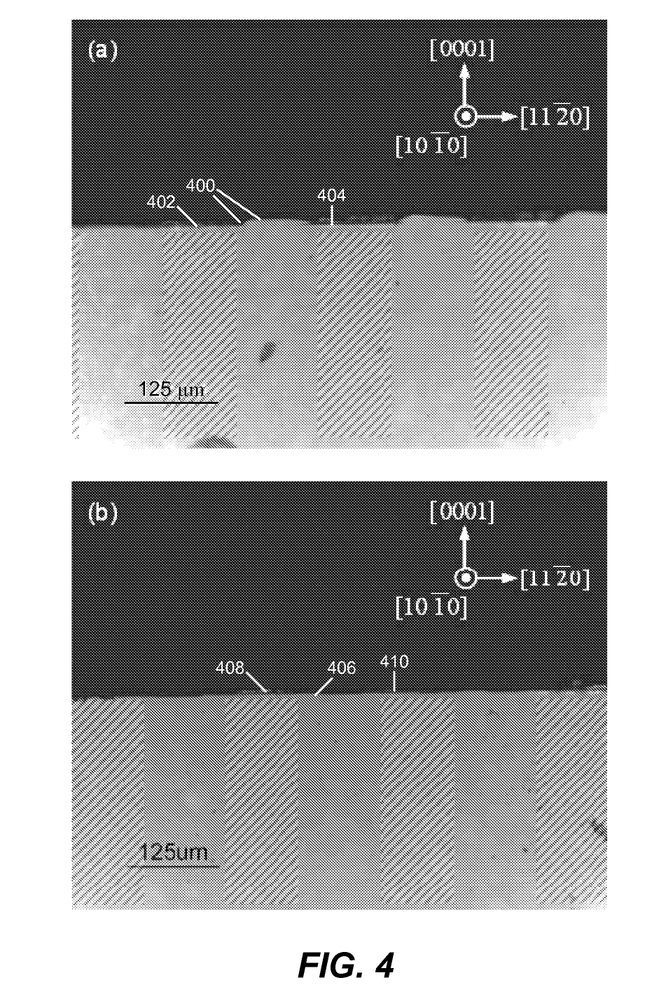

After the scribing process was completed, samples A and B were cleaved into bars similar in size and shape to the bars formed during conventional LD fabrication. Similar sample mounting and cleaving techniques were used for both samples. Representative optical micrographs of the surfaces of the p⁺⁺ contact layer 112 of samples A and B after cleaving are presented in FIGS. 4(a) and 4(b), respectively. Both figures were taken at relatively low magnification (20×) and show several skip-scribe steps. The shaded areas in the figures correspond to the regions that were scribed, whereas the unshaded areas correspond to the regions that were skipped. For sample A, the skipped region typically does not always cleave along a crystallographic plane, but often cracks in a non-crystallographic curved or angled line 400 connecting the two adjacent scribed lines 402, 404. However, for sample B, the skipped region consistently cleaves in a straight line 406 along the {0001} crystallographic plane, connecting the two adjacent scribed lines 408, 410. An inspection of several bars from each sample reveals the same trend. Although the exact mechanism for the improvement in the facet quality and cleave uniformity is unknown, the inventors speculate that it is related to accumulated strain energy in the anisotropically-strained thick n-type Al-containing CAL. In FIG. 4(a) and FIG. 4(b), the arrows indicate the [0001] and [11-20] crystal directions and the circle surrounding the dot indicates the [10-10] crystal direction.

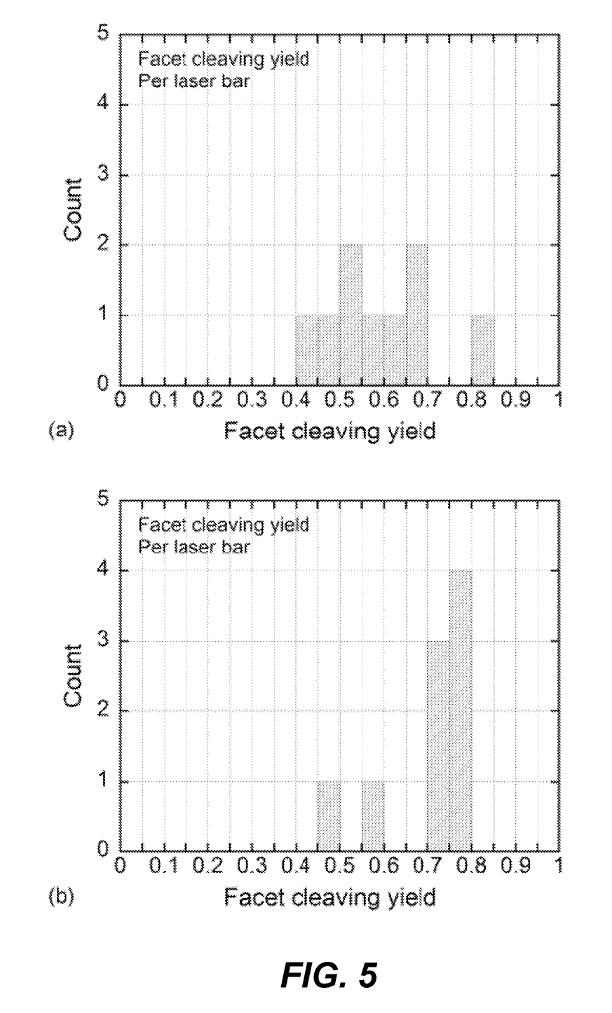

The data presented above in FIG. 3(a)-(b) and FIG. 4(a)-(b) provides qualitative evidence that facet cleaving yield is enhanced for samples with thick n-type Al-containing CALs. In FIG. 5, the inventors attempt to quantify the above observations. FIGS. 5(a) and 5(b) display histograms of facet yield per laser bar for samples A and B, respectively. Each laser bar contained approximately 20 skip regions. The quality of each cleave for each skip region of each laser bar was evaluated under an optical microscope. Skipped regions that were completely straight as observed by optical microscopy were categorized as successful cleaves, while skipped regions that were angled or curved in any way were categorized as unsuccessful cleaves. The facet yield per laser bar was then plotted as histogram for each sample. As shown in FIG. 5(a), the facet yield per bar for sample A lies in the range of 0.429 to 0.800, with an average facet yield per bar of 0.579 and a standard deviation of 0.113. In contrast, as shown in FIG. 5(b), the facet yield per bar for sample B lies in the range of 0.478 to 0.773, with an average facet yield per bar of 0.705 and a standard deviation of 0.103. Although the exact mechanism for the improvement in the facet cleaving yield is unknown, the inventors speculate that it is related to accumulated strain energy in the anisotropically-strained thick n-type Al-containing CAL.

Process Steps

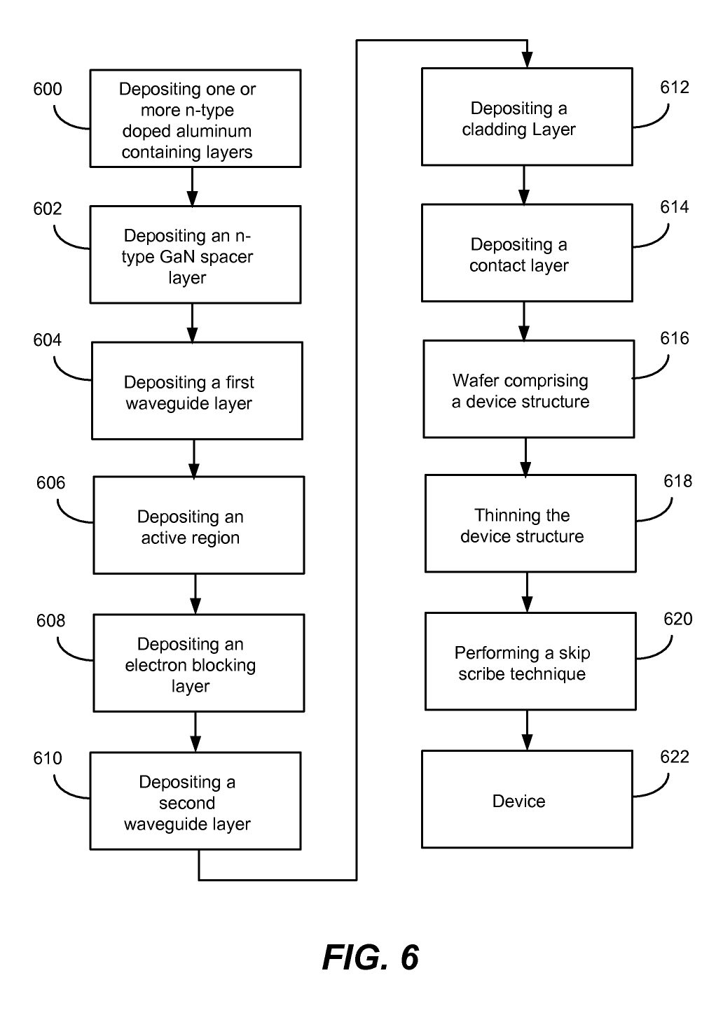

FIG. 6 is a flowchart illustrating a method of fabricating a semiconductor optoelectronic device. The method may comprise the following steps.

Block 600 represents depositing one or more n-type doped aluminum-containing layers, e.g., on an m-plane, non-polar plane, or semipolar plane of n-type GaN template, that can be used to assist with facet cleaving along a particular crystallographic plane of the LD. The n-type doped aluminum-containing layers may be thick enough for spontaneous cleaving of the device's facets acting as mirrors for the laser cavity. For example, the n-type doped aluminum-containing layers may be between 50 nm and 2000 nm thick, and may comprise AlGaN with compositions between 3% and 30% Al, although the present invention is not limited to this thickness and composition range. In one example, and without being bound to a particular scientific theory, the CAL is thick enough and/or has high enough Al composition such that there is a significant amount of strain energy present without being too thick and/or high in Al composition that it forms cracks, e.g., the thickness/composition may be just under the cracking limit (based on FIG. 1a of Ref 20, for example). However, as noted above, the present invention is not limited to this thickness/composition.

The template (104 in FIG. 1(b)), may be a III-nitride (e.g., GaN) substrate having the surface 146, and the surface may be a non-polar plane or semi-polar plane, or off-axis with respect to a non-polar plane, such that subsequently deposited III-nitride device layers are nonpolar or semipolar layers.

Block 602 represents depositing an n-GaN spacer layer on the n-type doped aluminum-containing layers.

Block 604 represents depositing a first waveguiding layer on the spacer layer or on the n-type doped aluminum-containing layers.

Block 606 represents depositing a quantum well active region on the first waveguiding layer, spacer layer, or on the n-type aluminum-containing layers. A quantum well active region may function as the waveguide core (e.g., the quantum well may be the waveguide core). The quantum well active region may provide enough material with a high index of refraction to effectively confine an optical mode of the device in the absence of the p-type doped aluminum-containing waveguide cladding layers, as shown in FIG. 2(b), for example.

However, while the quantum well active region, including quantum well layers, may be sufficiently thick to confine the laser's optical mode at least as well as shown in FIG. 2(b), the quantum well layers are typically sufficiently thin to be considered a quantum well and provide quantum confinement. The quantum well active region typically includes a plurality of quantum wells, including InGaN quantum wells having a thickness of typically (although not limited to) between 2 and 20 nm, and GaN barriers having a thickness of typically (although not limited to) between 5 and 20 nm. In one example, thicknesses greater than 4 nm for the quantum wells may be used, e.g., in an m-plane device, for example.

A closest one of the n-type doped aluminum-containing layers may be less than, or greater than, 500 nm away from the active region and may or may not have an effect of the distribution of the optical mode.

Block 608 represents depositing an AlGaN electron blocking layer on the quantum well active region.

Block 610 represents depositing a second waveguiding layer on the quantum well active region. One or more waveguiding layers in Blocks 604 and 610 may have a refractive index greater than that of GaN, for example. The quantum well active region and the waveguiding layers may provide enough material with a high index of refraction to effectively confine an optical mode of the device in the absence of the p-type doped aluminum-containing waveguide cladding layers.

Block 612 represents depositing a cladding layer on the second waveguide layer, for example an Mg doped p-GaN cladding layer.

Block 614 represents depositing a p⁺⁺ GaN contact layer on the cladding layer.

Block 616 represents the end result of the above steps, a wafer comprising optoelectronic device layers or structure. The depositing steps in Blocks 600-614 may comprise growing, e.g., by MOCVD growth or other growth methods (e.g., MBE etc.).

Block 618 represents thinning the device structure, e.g., by mechanical grinding and lapping, to a thickness of typically (but not limited to) 100 μm or below.

Block 620 represents performing a periodic skip-scribe technique on the wafer comprising the device structure, thereby preparing the wafer for facet cleaving into individual devices. The skip-scribe technique may comprise scribing the epitaxial side of the wafer (e.g., with a scribe such as a diamond stylus) with a collinear set of skip steps and scribe steps across the wafer. The scribe direction may be aligned with the a-axis of the crystal. During the skip steps, the scribe used to scribe the wafer may be lifted up from the surface of the wafer, leaving the wafer unscribed for a distance. This skip length is typically where a ridge waveguide LD structure would be located in the case of a fully processed LD sample. The skipped region spontaneously cleaves in a straight line along the {0001} crystallographic plane, connecting the two adjacent scribed lines.

Block 622 represents the end result of the method, an optoelectronic device such as a LD. Steps may be omitted or added as desired; for example other steps used in the processing of an operational LD device may be performed.

The semiconductor optoelectronic device of Block 622 may include a nonpolar or semipolar (Ga,Al,In,B)N LD comprising a waveguide core that provides sufficient optical confinement for the device's operation (e.g., sufficient optical confinement for lasing operation) in the absence of p-type doped aluminum-containing waveguide cladding layers, and one or more n-type doped aluminum-containing layers, on or under the waveguide core, although the n-type doped aluminum-containing layers are typically under the waveguide core or between the waveguide core and the substrate or GaN template.

The p-type doped aluminum-containing waveguide cladding layer may be defined as an aluminum-containing layer that is necessary, in a conventional device, to provide sufficient optical confinement for the conventional device's operation. For example, the p-type doped aluminum-containing waveguide cladding layer may be defined as an aluminum-containing layer that is used to provide sufficient optical confinement of light emitted from an InGaN quantum well active region in a conventional LD, the InGaN quantum wells in the quantum well active region of the conventional LD being c-plane polar and/or having a thickness of e.g., 4 nm or below.

The nonpolar or semipolar (Ga,Al,In,B)N LD may include a quantum well active region and/or one or more waveguiding layers with a refractive index greater than GaN. The quantum well active region may function as the waveguide core, or the quantum well active region and the waveguiding layers may function together as the waveguide core. For example, the nonpolar or semipolar (Ga,Al,In,B)N LD may include a quantum well active region, and one or more waveguiding layers, with a refractive index greater than that of GaN, optically coupled to the quantum well active region, the waveguiding layers and the quantum well active region functioning together as the waveguide core. The quantum well active region, or the quantum well active region and the waveguiding layers, may provide enough material with a high index of refraction to effectively confine an optical mode of the device in the absence of p-type doped aluminum-containing waveguide cladding layers.

A closest one of the n-type doped aluminum-containing layers may be less than, or greater than, 500 nm away from the active region.

The device may be free of AlGaN cladding layers, or comprise AlInGaN cladding layers positioned to act as a cladding for the waveguide core, for example as in a green light emitting semipolar LD.

The device may further comprise a laser cavity bounded by a first facet 142 and a second facet 144, at opposite ends of the laser cavity, that function as the laser cavity's mirrors, wherein the first facet 142 and the second facet 144 are “as cleaved” facets (e.g., without further polishing) that are more planar and straighter 406 in cross-section as compared to the “as cleaved” facets in a device structure without the n-type doped aluminum-containing layers (e.g, as compared to the cleaved surface 400 in FIG. 4(a)).

In one example, the straight facets are characterized by an angle between the “as cleaved” facets and laser ridge that is (but not limited to) less than 5 degrees.

Thus, the n-type doped aluminum-containing layers may be used to assist with facet cleaving 142, 144 along a particular crystallographic plane of the LD. For example, when the LD is grown on an m-plane plane GaN substrate along an m-axis direction, the cleaved facet's 142, 144 surface may be a c-plane of the wurtzite crystal structure (i.e., the c-axis direction perpendicular to the cleaved facet 142, 144). However, devices may be grown on other planes and facets cleaved along other directions.

Possible Modifications and Variations

Variations in MOCVD growth conditions such as growth temperature, growth pressure, VIII ratio, precursor flows, and source materials are also possible without departing from the scope of the present invention. Control of interface quality is an important aspect of the process and is directly related to the flow switching capabilities of particular reactor designs. Continued optimization of the growth conditions should result in more accurate compositional and thickness control of the nonpolar or semipolar (Ga,Al,In,B)N thin films described above.

The (Ga,Al,In,B)N LDs described above were comprised of multiple homogenous layers grown directly on free-standing nonpolar GaN substrates. However, the scope of this invention also covers (Ga,Al,In,B)N LDs comprised of multiple layers having varying or graded compositions.

Additional impurities or dopants can also be incorporated into the nonpolar or semipolar (Ga,Al,In,B)N thin films described in this invention. For example, Fe, Mg, Si, and Zn are frequently added to various layers in (Ga,Al,In,B)N heterostructures to alter the conduction properties of those and adjacent layers. The use of such dopants and others not listed here are within the scope of the invention.

The scope of this invention also covers more than just the one nonpolar orientation (m-plane) cited in the technical description. This idea is also pertinent to all nonpolar and semipolar planes that can be used for growing (Ga,Al,In,B)N-based semiconductor devices. The term “nonpolar plane” includes the {11 2̅0} planes, known collectively as a-planes, and the {10 1̅0} planes, known collectively as m-planes. The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index.

This invention also covers the selection of particular crystal polarities. The use of curly brackets, { }, throughout this document denotes a family of symmetry-equivalent planes. Thus, the {10 1̅2} family includes the (10 1̅2), ( 1̅012), (1 1̅02), ( 1̅102), (01 1̅2), and (0 1̅12) planes. All of these planes are Ga-polarity, meaning that the crystal's c-axis points away from the substrate. Likewise, the {10 1̅2̅} family includes the (10 1̅2̅), ( 1̅01 2̅), (1 1̅0 2̅), ( 1̅10 2̅), (01 1̅2̅), and (0 1̅1 2̅) planes. All of these planes are N-polarity, meaning that the crystal's c-axis will point towards the substrate. All planes within a single crystallographic family are equivalent for the purposes of this invention, though the choice of polarity can affect the behavior of the growth process. In some applications, it would be desirable to grow on N-polarity planes, while in other cases growth on Ga-polarity planes would be preferred. Both polarities are acceptable for the practice of this invention.

Moreover, substrates other than free-standing nonpolar or semipolar (Ga,Al,In,B)N substrates could be used for (Ga,Al,In,B)N LD growth. The scope of this invention includes the growth of nonpolar or semipolar (Ga,Al,In,B)N LDs on all possible crystallographic orientations of all possible foreign substrates. These foreign substrates include, but are not limited to, silicon carbide, gallium nitride, silicon, zinc oxide, boron nitride, lithium aluminate, lithium niobate, germanium, aluminum nitride, lithium gallate, partially substituted spinels, and quaternary tetragonal oxides sharing the γ-LiAlO₂ structure.

Furthermore, variations in nonpolar or semipolar (Ga,Al,In,B)N nucleation (or buffer) layers and nucleation layer growth methods are acceptable for the practice of this invention. The growth temperature, growth pressure, orientation, and composition of the nucleation layers need not match the growth temperature, growth pressure, orientation, and composition of the subsequent nonpolar or semipolar thin films and heterostructures. The scope of this invention includes the growth of nonpolar or semipolar (Ga,Al,In,B)N LDs on all possible substrates using all possible nucleation layers and nucleation layer growth methods.

The nonpolar GaN LDs described above were grown on free-standing nonpolar GaN substrates. However, the scope of this invention also covers nonpolar or semipolar (Ga,Al,In,B)N LDs grown on epitaxial laterally overgrown (ELO) (Ga,Al,In,B)N templates. The ELO technique is a method of reducing the density of threading dislocations (TD) in subsequent epitaxial layers. Reducing the TD density can lead to improvements in device performance. For c-plane (Ga,Al,In,B)N LDs, these improvements can include increased internal quantum efficiencies, reduced threshold current densities, and longer device lifetimes [Ref 17]. These advantages will be pertinent to all nonpolar or semipolar (Ga,Al,In,B)N LDs grown on ELO templates.

The technical description presented above discussed the growth of nonpolar (Ga,Al,In,B)N LDs on free-standing nonpolar GaN substrates that were grown by hydride vapor phase epitaxy (HVPE) in the c-direction and then sliced to expose the m-plane surface. Free-standing nonpolar or semipolar (Ga,Al,In,B)N substrates may also be created by removing a foreign substrate from a thick nonpolar or semipolar (Ga,Al,In,B)N layer, by sawing a bulk (Ga,Al,In,B)N ingot or boule into individual nonpolar or semipolar (Ga,Al,In,B)N wafers, or by any other possible crystal growth or wafer manufacturing technique. The scope of this invention includes the growth of nonpolar or semipolar (Ga,Al,In,B)N LDs on all possible free-standing nonpolar or semipolar (Ga,Al,In,B)N wafers created by all possible crystal growth methods and wafer manufacturing techniques.

The technical description presented above discussed growing ACF (Ga,Al,In,B)N LDs with a 5 period undoped InGaN/GaN MQW structure with 8 nm InGaN QWs and 8 nm GaN barriers to provide sufficient optical confinement for the device's operation. However, the devices could have also contained one or more waveguiding layers with a refractive index greater than that of GaN. In this alternative structure, the quantum well active region and the waveguiding layers would function together as the waveguide core. The use of any waveguiding layers with a refractive index greater than that of GaN is suitable for the practice of this invention. For example, in one embodiment, a relatively thick, high In composition InGaN waveguiding layers (which comprise the bulk of the waveguide core) surrounding a single 5 nm quantum well could be used, in which case the total active region thickness is only 5 nm.

However, in some embodiments of the present invention, the present invention does not require a particular active region design. For example, in these embodiments, the present invention may simply provide a device which contains n-type Al-containing layers of some sort (cladding or otherwise) to assist with facet cleaving (but which doesn't contain any p-type Al-containing cladding layers).

The technical description presented above discussed using 1 μm n-type Al_{0.06}Ga_{0.94}N CALs to improve mirror facet cleaving yield for nonpolar or semipolar (Ga,Al,In,B)N LDs. However, one or more n-type Al-containing (Ga,Al,In,B)N layers of any composition or thickness could have used to improve facet cleaving yield. The use of any n-type Al-containing (Ga,Al,In,B)N layer to improve facet cleaving yield is suitable for the practice of this invention.

The technical description presented above discussed growing ACF (Ga,Al,In,B)N LDs with 1 μm Si-doped n-Al_{0.06}Ga_{0.94}N CALs located 1 μm below the InGaN/GaN MQW.

As illustrated in FIG. 2(b), the 1 μm Si-doped n-Al_{0.06}Ga_{0.94}N CAL had little effect on the optical mode when it was located 1 μm below the InGaN/GaN MQW. However, the n-type Al-containing CAL could have been located much closer to the active region so that it had a more significant effect on the optical mode. The scope of this invention covers all nonpolar or semipolar (Ga,Al,In,B)N LDs with n-type Al-containing CALs, regardless of the placement of the n-type Al-containing CALs relative to the active region. Any nonpolar or semipolar (Ga,Al,In,B)N LD structure containing an n-type Al-containing CAL is suitable for the practice of this invention, provided that the device does not contain any p-type Al-containing waveguide cladding layers.

The AlGaN CAL may also apply to LDs using lattice matched quaternary AlInGaN cladding, because these devices may have no tensile strain, just like AlGaN cladding free LDs. Thus, the AlGaN CAL may be used in a semipolar green light emitting LD comprising AlInGaN cladding.

Advantages and Improvements

As noted above, existing practice is to grow (Ga,Al,In,B)N LDs along the polar [0001] c-direction. The associated polarization-induced electric fields and inherently large effective valence band density of states are detrimental to the performance of state-of-the-art c-plane (Ga,Al,In,B)N LDs. Growth of (Ga,Al,In,B)N LDs on nonpolar or semipolar planes could significantly improve device performance by decreasing polarization effects and reducing the effective valence band density of states through anisotropic strain-induced splitting of the top two valence bands. Decreasing polarization-induced electric fields and reducing the effective valence band density of states should decrease the current densities necessary to generate optical gain in (Ga,Al,In,B)N LDs. This should lead to significantly less heating in (Ga,Al,In,B)N LDs, which should result in longer device lifetimes and higher production yields for device manufacturers.

However, with the difficulties inherent to cleaving along polar crystal planes, it will be difficult for device manufacturers to realize the expected advantages of nonpolar or semipolar (Ga,Al,In,B)N devices. This invention describes a structure that can be used to improve the facet cleaving yield of (Ga,Al,In,B)N LDs grown on nonpolar or semipolar (Ga,Al,In,B)N substrates, without the need for growing thick p-type Al-containing waveguide cladding layers. Improved facet cleaving yields should lead to a number of advantages for nonpolar and semipolar (Ga,Al,In,B)N device manufacturers, including, but not limited to, better overall device yield, higher facet stability, higher catastrophic optical damage (COD) levels, and longer device lifetimes.

In the case of conventional (Ga,Al,In,B)N LDs, thick n-type and p-type Al-containing waveguide cladding layers could be used to improve the facet cleaving yield. However, the use of p-type Al-containing waveguide cladding layers in conventional (Ga,Al,In,B)N LDs can introduce several manufacturing-related problems. In general, p-type Al-containing layers are usually higher resistivity than comparable p-type GaN layers, resulting in higher operation voltages for devices with p-type Al-containing layers than devices without p-type Al-containing layers. In addition, p-type Al-containing layers are typically grown at higher growth temperatures than comparable p-type GaN layers, which can thermally degrade high-indium-content InGaN quantum wells. The realization of nonpolar or semipolar (Ga,Al,In,B)N LDs without p-type Al-containing waveguide cladding layers should alleviate many of these problems.

Further information on the present invention can be found in [Refs. 21-23].

### REFERENCES

The following references are incorporated by reference herein.
1. K. C. Kim, M. C. Schmidt, H. Sato, F. Wu, N. Fellows, Z. Jia, M. Saito, S. Nakamura, S. P. DenBaars, and J. S. Speck, Appl. Phys. Lett., 91, 181120 (2007).
2. D. F. Feezell, M. C. Schmidt, R. M. Farrell, K. C. Kim, M. Saito, K. Fujito, D. A. Cohen, J. S. Speck, S. P. DenBaars, and S. Nakamura, Jpn. J. Appl. Phys., 46, L284 (2007).
3. R. M. Farrell, D. F. Feezell, M. C. Schmidt, D. A. Haeger, K. M. Kelchner, K. Iso, H. Yamada, M. Saito, K. Fujito, D. A. Cohen, J. S. Speck, S. P. DenBaars, and S. Nakamura, Jpn. J. Appl. Phys., 46, L761 (2007).
4. K. M. Kelchner, Y. D. Lin, M. T. Hardy, C. Y. Huang, P. S. Hsu, R. M. Farrell, D. A. Haeger, H. C. Kuo, F. Wu, K. Fujito, D. A. Cohen, A. Chakraborty, H. Ohta, J. S. Speck, S. Nakamura, and S. P. DenBaars, “Nonpolar AlGaN-cladding-free Blue Laser Diodes with InGaN Waveguiding,” to be published in Appl. Phys. Express.
5. K. Okamoto, H. Ohta, S. F. Chichibu, J. Ichihara, and H. Takasu, Jpn. J. Appl. Phys., 46, L187 (2007).
6. K. Okamoto, T. Tanaka, M. Kubota, and H. Ohta, Jpn. J. Appl. Phys., 46, L820 (2007).
7. T. Takeuchi, S. Sota, M. Katsuragawa, M. Komori, H. Takeuchi, H. Amano, and I. Akasaki, Jpn. J. Appl. Phys., 36, L382 (1997).
8. J. S. Im, H. Kollmer, J. Off, A. Sohmer, F. Scholz, and A. Hangleiter, Phys. Rev. B, 57, R9435 (1998).
9. F. Della Sala, A. Di Carlo, P. Lugli, F. Bernardini, V. Fiorentini, R. Scholz, and J. M. Jancu, Appl. Phys. Lett., 74, 2002 (1999).
10. M. Suzuki and T. Uenoyama, Jpn. J. Appl. Phys., 35, L953 (1996).
11. E. Yablonovitch and E. O. Kane, J. Lightwave Tech., 4, 504 (1986).
12. P. Waltereit, O. Brandt, A. Trampert, H. T. Grahn, J. Menninger, M. Ramsteiner, M. Reiche, and K. H. Ploog, Nature, 406, 865 (2000).
13. S. H. Park and D. Ahn, Appl. Phys. Lett. 90, 013505 (2007).
14. N. F. Gardner, J. C. Kim, J. J. Wierer, Y. C. Shen, and M. R. Krames, Appl. Phys. Lett., 86, 111101 (2005).
15. M. Kubota, K. Okamoto, T. Tanaka, and H. Ohta, Appl. Phys. Lett., 92, 011920 (2008).
16. M. Hansen: Dr. Thesis, Materials Department, University of California, Santa Barbara (2001).
17. S. Nakamura, M. Senoh, S. Nagahama, N. Iwasa, T. Yamada, T. Matsushita, H. Kiyoku, Y. Sugimoto, T. Kozaki, H. Umemoto, M. Sano, and K. Chocho, Appl. Phys. Lett., 72, 211 (1998).
18. S. Nakamura and G. Fasol, The Blue Laser Diode, (Springer, Heidelberg, 1997). This book provides an overview of c-plane (Ga,Al,In,B)N optoelectronics technology.
19. L. Coldren and S. Corzine, Diode Lasers and Photonic Integrated Circuits, (Wiley, New York, 1995). Chapters 4 and Appendices 8-11 discuss the theory relevant to the design of strained quantum well lasers.
20. E. C. Young et al., Appl. Phys. Lett., 96, 041913 (2010).
21. Presentation Slides given by Shuji Nakamura, entitled “An overview of Laser Diodes (LDs) and Light Emitting Diodes (LEDs) Research at SSLEC,” at the 2009 Annual Review for Solid State Lighting and Energy Center (SSLEC), University of California, Santa Barbara (Nov. 5, 2009).
22. Presentation Slides given by Matthew T. Hardy, entitled “Backend Processing for m-plane Cleaved Facet Laser Diodes and Superluminescent Diodes,” at the 2009 Annual Review for SSLEC, University of California, Santa Barbara (Nov. 6, 2009).
23. Unpublished manuscript by Matthew T. Hardy, Robert M. Farrell, Po S. Hsu, Daniel A. Haeger, Kathryn M. Kelchner, Kenji Fujito, Arpan Chakraborty, Daniel A. Cohen, Shuji Nakamura, James S. Speck, and Steven P. DenBaars, entitled “Effect of n-AlGaN Cleave Assistance Layers on the Morphology of c-plane Cleaved Facets for m-plane InGaN/GaN Lasers Diode Structures.”

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A semiconductor optoelectronic device, comprising:
a nonpolar or semipolar (Ga,Al,In,B)N laser diode including:
(i) a waveguide core that provides sufficient optical confinement for the device's operation in the absence of p-type doped aluminum-containing waveguide cladding layers, and
(ii) one or more n-type doped aluminum-containing layers, on or under the waveguide core.

2. The device of claim 1, wherein the one or more n-type doped aluminum-containing layers assist with facet cleaving along a particular crystallographic plane of the laser diode.

3. The device of claim 1, wherein the p-type doped aluminum-containing waveguide cladding layer is defined as an aluminum-containing layer that is used to provide sufficient optical confinement of light emitted from InGaN quantum wells in a conventional laser diode, the InGaN quantum wells in the conventional laser diode having a thickness of 4 nm or below.

4. The device of claim 1, wherein the nonpolar or semipolar (Ga,Al,In,B)N laser diode includes a quantum well active region that functions as the waveguide core.

5. The device of claim 4, wherein the quantum well active region provides enough material with a high index of refraction to effectively confine an optical mode of the device in the absence of the p-type doped aluminum-containing waveguide cladding layers.

6. The device of claim 5, wherein a closest one of the n-type doped aluminum-containing layers is less than 500 nm away from the active region.

7. The device of claim 5, wherein a closest one of the n-type doped aluminum-containing layers is greater than 500 nm away from the active region.

8. The device of claim 1, wherein the nonpolar or semipolar (Ga,Al,In,B)N laser diode includes a quantum well active region and one or more waveguiding layers, with a refractive index greater than that of GaN, optically coupled to the quantum well active region, the waveguiding layers and the quantum well active region functioning together as the waveguide core.

9. The device of claim 8, wherein the quantum well active region and the waveguiding layers provide enough material with a high index of refraction to effectively confine an optical mode of the device in the absence of the p-type doped aluminum-containing waveguide cladding layers.

10. The device of claim 9, wherein a closest one of the n-type doped aluminum-containing layers is less than 500 nm away from the active region.

11. The device of claim 9, wherein a closest one of the n-type doped aluminum-containing layers is greater than 500 nm away from the active region.

12. The device of claim 1, wherein the device is free of AlGaN cladding layers.

13. The device of claim 1, wherein the device comprises AlInGaN cladding layers positioned to act as a cladding for the waveguide core.

14. The device of claim 1, further comprising a laser cavity bounded by a first facet and a second facet, at opposite ends of the laser cavity, that function as the laser cavity's mirrors, wherein the first facet and the second facet are “as cleaved” facets that are more planar and straighter as compared to “as cleaved” facets in a device structure without the n-type doped aluminum-containing layers.

15. The device of claim 1, wherein a thickness and position of the n-type doped aluminum-containing layers does not affect the optical confinement.

16. A method of fabricating semiconductor optoelectronic device, comprising:
fabricating a nonpolar or semipolar (Ga,Al,In,B)N laser diode including:
(i) a waveguide core that provides sufficient optical confinement for the device's operation in the absence of p-type doped aluminum-containing waveguide cladding layers, and
(ii) one or more n-type doped aluminum-containing layers, on or under the waveguide core.

17. The method of claim 16, wherein the n-type doped aluminum-containing layers assist with facet cleaving along a particular crystallographic plane of the laser diode.

18. The method of claim 16, wherein the p-type doped aluminum-containing waveguide cladding layer is defined as an aluminum-containing layer that is used to provide sufficient optical confinement of light emitted from InGaN quantum wells in a conventional laser diode, the InGaN quantum wells in the conventional laser diode having a thickness of 4 nm or below.

19. The method of claim 16, wherein the nonpolar or semipolar (Ga,Al,In,B)N laser diode includes a quantum well active region that functions as the waveguide core.

20. The method of claim 19, wherein the quantum well active region provides enough material with a high index of refraction to effectively confine an optical mode of the device in the absence of the p-type doped aluminum-containing waveguide cladding layers.

21. The method of claim 20 wherein a closest one of the n-type doped aluminum-containing layers is less than 500 nm away from the active region.

22. The method of claim 20 wherein a closest one of the n-type doped aluminum-containing layers is greater than 500 nm away from the active region.

23. The method of claim 16, wherein the nonpolar or semipolar (Ga,Al,In,B)N laser diode includes a quantum well active region and one or more waveguiding layers, with a refractive index greater than that of GaN, optically coupled to the quantum well active region, the waveguiding layers and the quantum well active region functioning together as the waveguide core.

24. The method of claim 23, wherein the quantum well active region and the waveguiding layers provide enough material with a high index of refraction to effectively confine an optical mode of the device in the absence of p-type doped aluminum-containing waveguide cladding layers.

25. The method of claim 24, wherein a closest one of the n-type doped aluminum-containing layers is less than 500 nm away from the active region.

26. The method of claim 24, wherein a closest one of the n-type doped aluminum-containing layers is greater than 500 nm away from the active region.
